(19) United States
(12) Patent Application Publication
(10) Pub. No.: US 2026/0087977 A1
(43) Pub. Date: Mar. 26, 2026

(54) DISPLAY PANEL AND DISPLAY DEVICE

(71) Applicant: Tianma Advanced Display Technology Institute (Xiamen) Co., Ltd., Xiamen (CN)

(72) Inventor: Yingteng ZHAI, Xiamen (CN)

(73) Assignee: Tianma Advanced Display Technology Institute (Xiamen) Co., Ltd., Xiamen (CN)

(21) Appl. No.: 19/407,567

(22) Filed: Dec. 3, 2025

(30) Foreign Application Priority Data
Jun. 30, 2025 (CN) 202510897298.9

(51) Int. Cl. G09G 3/32; G11C 19/28; H10H 29/32; H10H 29/49

(52) U.S. Cl. CPC G09G 3/32; G11C 19/287; H10H 29/32; H10H 29/49; G09G 2310/0286; G09G 2310/08; G09G 2320/0233

(57) ABSTRACT

Provided are a display panel and a display device. The display region of the display panel includes multiple shift register circuit groups. The shift register circuit group includes multiple shift register units disposed sequentially in a first direction. The multiple shift register circuit groups are arranged in a second direction. The first direction and the second direction intersect. The shift register circuit group is configured to output a first scan signal and includes at least a first shift register circuit group and a second shift register circuit group, which are respectively connected to first scan signals of different rows. The display region further includes multiple signal lines extending in the first direction. The signal line includes multiple signal line groups. The signal line group is electrically connected to a respective shift register circuit group, and different signal line groups are electrically connected to different shift register circuit groups.

### CROSS-REFERENCE TO RELATED APPLICATION(S)

This application claims priority to Chinese Patent Application No. 202510897298.9 filed Jun. 30, 2025, the disclosure of which is incorporated herein by reference in its entirety.

### TECHNICAL FIELD

The present disclosure relates to the field of display technology, and in particular, to a display panel and a display device.

### BACKGROUND

Light-emitting diode (LED) display panels, such as micro-LED display panels and mini-LED display panels, have many advantages of self-luminescence, low driving voltage, high luminescence efficiency, short response time, high definition and contrast ratio, and the like, and have gradually become a research hotspot in the field of display technology.

A display panel includes pixel circuits arranged in an array and a generation circuit providing drive signals for the pixel circuits, such as the generation circuit for a sweep signal (SWEEP). The generation circuit of the sweep signal generates SWEEP by gating the sweep clock signal. The sweep clock signal is provided by multiple signal lines, and the distance between the signal lines and the generation circuit of the sweep signal is relatively small; therefore, the signal lines are too concentrated, which is not conducive to the back-routing process.

### SUMMARY

Embodiments of the present disclosure provide a display panel and a display device to reduce the arrangement density of signal lines in the display panel and improve the uniformity of image display.

In a first aspect, an embodiment of the present disclosure provides a display panel. The display panel includes a substrate and a display region. The display region includes multiple shift register circuit groups, a shift register circuit group includes multiple shift register units disposed sequentially in a first direction, the multiple shift register circuit groups are arranged in a second direction, the first direction and the second direction intersect, the multiple shift register circuit groups are each configured to output a first scan signal, the multiple shift register circuit groups includes at least a first shift register circuit group and a second shift register circuit group, and the first shift register circuit group and the second shift register circuit group are respectively connected to first scan signal lines of different rows. The display region further includes multiple signal lines extending in the first direction, the multiple signal lines include multiple signal line groups, a signal line group is electrically connected to a respective shift register circuit group of the multiple shift register circuit groups, and different signal line groups are electrically connected to different shift register circuit groups.

In a second aspect, an embodiment of the present disclosure provides a display device including the display panel provided in any of the embodiments of the present disclosure.

### BRIEF DESCRIPTION OF DRAWINGS

FIG. 1 is a schematic structural diagram of a display panel in the related art;

FIG. 2 is a schematic structural diagram of a display panel according to an embodiment of the present disclosure;

FIG. 3 is a schematic structural diagram of another display panel according to an embodiment of the present disclosure;

FIG. 4 is a timing diagram of a sweep clock signal line according to an embodiment of the present disclosure;

FIG. 5 is a schematic structural diagram of another display panel according to an embodiment of the present disclosure;

FIG. 6 is a schematic structural diagram of another display panel according to an embodiment of the present disclosure;

FIG. 7 is a schematic structural diagram of another display panel according to an embodiment of the present disclosure;

FIG. 8 is a schematic structural diagram of another display panel according to an embodiment of the present disclosure;

FIG. 9 is a schematic structural diagram of another display panel according to an embodiment of the present disclosure;

FIG. 10 is a schematic structural diagram of another display panel according to an embodiment of the present disclosure;

FIG. 11 is a schematic structural diagram of an auxiliary shift register unit according to an embodiment of the present disclosure;

FIG. 12 is a schematic structural diagram of a shift register unit according to an embodiment of the present disclosure;

FIG. 13 is a schematic structural diagram of another display panel according to an embodiment of the present disclosure;

FIG. 14 is a schematic structural diagram of another display panel according to an embodiment of the present disclosure;

FIG. 15 is a schematic structural diagram of another display panel according to an embodiment of the present disclosure;

FIG. 16 is a schematic structural diagram of another display panel according to an embodiment of the present disclosure;

FIG. 17 is a schematic structural diagram of a display device according to an embodiment of the present disclosure; and

FIG. 18 is a schematic structural diagram of another display device according to an embodiment of the present disclosure.

### DETAILED DESCRIPTION

The present disclosure will be further described in detail in conjunction with the drawings and embodiments below. It is to be understood that specific embodiments described herein are merely used for explaining the present disclosure and are not intended to limit the present disclosure. It is also to be noted that, for ease of description, only some, but not all, of the structures related to the present disclosure are shown in the drawings.

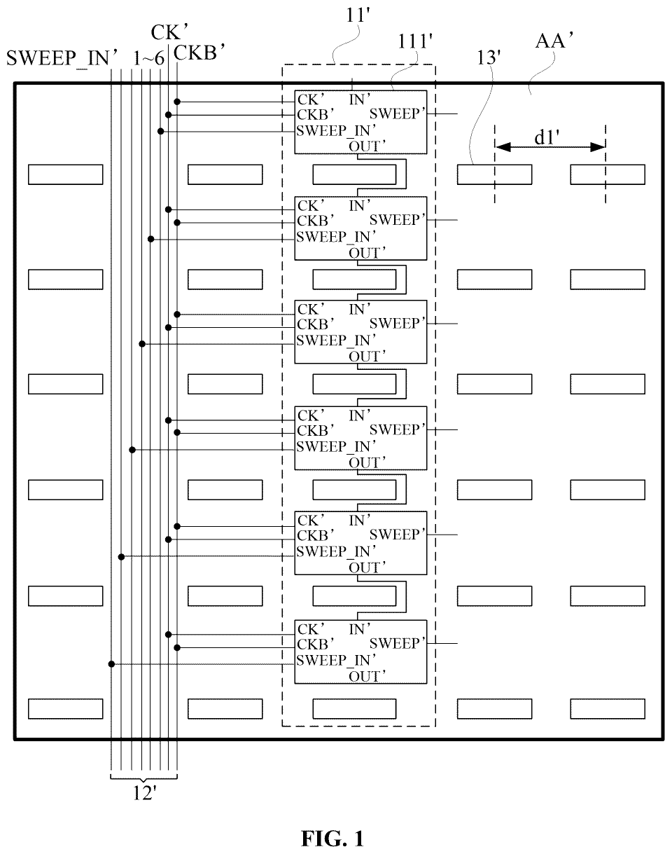

FIG. 1 is a schematic structural diagram of a display panel in the related art. In order to further reduce the width of the frame, the shift register circuit group may be disposed in the display region. As shown in FIG. 1, a shift register circuit group 11′ is disposed in a display region AA′, and a signal line 12′ corresponding to the shift register circuit group 11′ also needs to be disposed in the display region AA′. The signal lines 12′ are disposed in a concentrated manner, and the distance between the signal line 12′ and the shift register circuit group 11′ is less than a spacing d1′ between two pixels (the spacing between centers of two pixel circuits 13′). In the related art, the distance between the signal line 12′ and the shift register circuit group 11′ is too close, resulting in an excessively large number of signal lines 12′ within a small range, which easily causes the problem of uniform display. In addition, during the back-routing of the signal lines 12′ (the signal lines 12′ are led from the side of the substrate facing the shift register circuit group 11′ to the side of the substrate facing away from the shift register circuit group 11′ through metal lines), the excessively dense wiring makes the back-routing process more difficult.

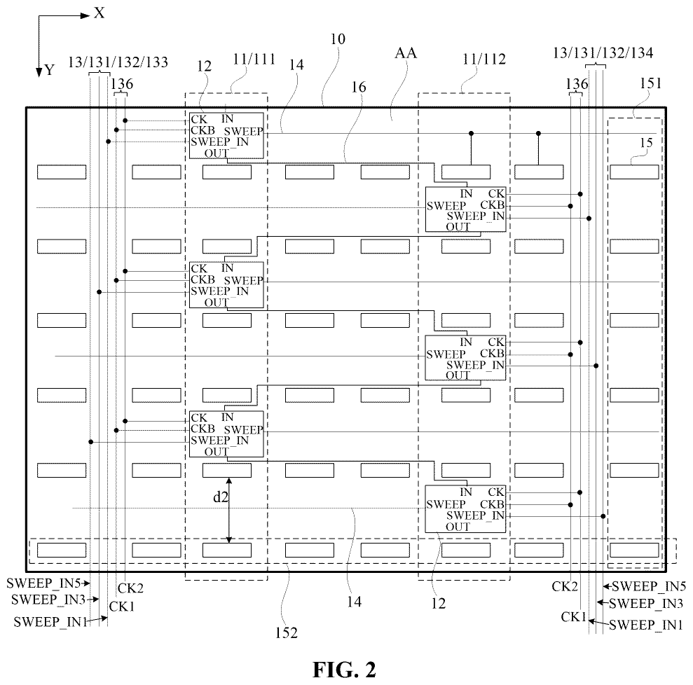

To solve the above problems, an embodiment of the present disclosure provides a display panel. As shown in FIG. 2, FIG. 2 is a schematic structural diagram of a display panel according to an embodiment of the present disclosure. The display panel includes a substrate 10 and a display region AA. The display region AA includes multiple shift register circuit groups 11. A shift register circuit group 11 includes multiple shift register units 12 disposed sequentially in a first direction Y. The multiple shift register circuit groups 11 are arranged in a second direction X. The first direction Y and the second direction X intersect. The shift register circuit groups 11 are each configured to output a first scan signal. The shift register circuit groups 11 include at least a first shift register circuit group 111 and a second shift register circuit group 112. The first shift register circuit group 111 and the second shift register circuit group 112 are respectively connected to first scan signal lines 14 of different rows. The display region AA further includes multiple signal lines 13 extending in the first direction Y. The signal lines 13 include multiple signal line groups 131. A signal line group 131 is electrically connected to a respective shift register circuit group 11. Different signal line groups 131 are electrically connected to different shift register circuit groups 11.

In embodiments of the present disclosure, the display region of the display panel includes the multiple shift register circuit groups arranged sequentially in the second direction, and the multiple shift register circuit groups are each configured to output the first scan signal. Each shift register circuit group includes the shift register units disposed sequentially in the first direction. At least the first shift register circuit group and the second shift register circuit group exist in the shift register circuit groups. The first shift register circuit group and the second shift register circuit group are respectively connected to the first scan signal lines of different rows. The display region further includes the signal lines extending in the first direction, and the signal line is configured to output a corresponding signal to drive the shift register circuit group to work. It is to be noted that the signal lines are divided into the multiple signal line groups, different signal line groups are electrically connected to different shift register circuit groups, and the multiple shift register circuit groups cooperate to output the first scan signals to first scan signal lines of various rows in the display region. In this embodiment, different signal line groups are electrically connected to different shift register circuit groups, the signal lines may be dispersedly disposed in the vicinity of different shift register circuit groups, thereby effectively preventing the signal lines from being centrally disposed in the relatively small region, preventing an excessively small distance between the signal line and the shift register circuit group, reducing the wiring density of the signal line, and simplifying the difficulty of the back-routing process. Furthermore, the signal lines which are dispersedly disposed prevent excessively dense wiring, thereby effectively improving the uniformity of image display.

The above is the core idea of the present disclosure, and the technical solutions of the embodiments of the present disclosure will be described clearly and completely in connection with the accompanying drawings in the embodiments of the present disclosure below. Based on the embodiments of the present disclosure, all other embodiments obtained by those skilled in the art without requiring creative efforts shall all fall within the scope of protection of the present disclosure.

The display panel includes a substrate, a circuit structure layer, and a display element layer. The circuit structure layer and the display element layer are disposed on a side of the substrate. As shown in FIG. 2, the circuit structure layer is formed on the substrate 10, and the circuit structure layer includes multiple pixel circuits 15 arranged in an array. The circuit structure layer is further provided with multiple shift register circuit groups 11. In this embodiment, the display panel adopts a frameless design, and the shift register circuit groups 11 are disposed in the display region AA. For an LED display panel, a micro-LED display panel, or a mini-LED display panel, the size of the pixel circuit 15 is relatively small, and the shift register circuit group 11 may be formed in a gap region between adjacent pixel circuits 15. The multiple shift register circuit groups 11 are each configured to output a first scan signal, and in this embodiment, the first scan signal may be a gate scan signal, a light-emitting control signal, a sweep signal, or other scan signals. In this embodiment, the specific type of the first scan signal is not particularly limited. It is to be noted that the first scan signal mentioned in the embodiment of the present disclosure is illustrated by using the sweep signal as an example.

Multiple first scan signal lines 14 extending in the second direction X are disposed in the display region AA, the multiple first scan signal lines 14 are arranged in the first direction Y, the first direction Y and the second direction X intersect. In one or more embodiments, the first direction Y and the second direction Y are perpendicular to each other. Each row of first scan signal lines 14 are configured to output the first scan signal to multiple pixel circuits 15. The shift register circuit group 11 includes multiple shift register units 12 disposed sequentially in the first direction Y, and each shift register unit 12 is capable of outputting one first scan signal to a corresponding first scan signal line 14. The first scan signal line 14 may be electrically connected to one row of pixel circuits 15 extending in the second direction X, to provide a drive signal to the row of pixel circuits 15. For convenience of illustration, only a schematic diagram in which the first scan signal line 14 is electrically connected to some pixel circuits 15 is shown in FIG. 2; however, in an actual application scenario, the first scan signal line 14 needs to be electrically connected to each pixel circuit 15 of the corresponding row of pixel circuits 15 to achieve scanning of the pixel circuits 15. It is to be noted that shift register units 12 in different shift register circuit groups 11 are connected to first scan signal lines 14 of different rows. Exemplarily, as shown in FIG. 2, the multiple shift register circuit groups 11 include at least a first shift register circuit group 111 and a second shift register circuit group 112. The shift register units 12 of the first shift register circuit group 111 output the first scan signal to a first scan signal line 14 of a first row, and the shift register units 12 of the second shift register circuit group 112 output the first scan signal to a first scan signal line 14 of a second row. The multiple shift register circuit groups 11 cooperate with each other to output the first scan signal to the first scan signal lines 14 of various rows in the display region AA.

The multiple signal lines 13 extending in the first direction Y are also disposed in the display region AA, and the signal lines 13 are each configured to provide a drive signal to the shift register circuit group 11. In this embodiment, the signal lines 13 may include multiple signal line groups 131, and each signal line group 131 includes at least one signal line 13. Different signal line groups 131 provide drive signals for different shift register circuit groups 11. Exemplarily, as shown in FIG. 2, one signal line group 131 is electrically connected to the first shift register circuit group 111, and another signal line group 131 is electrically connected to the second shift register circuit group 112. That is, in this embodiment, when cascaded shift register units 111′ in the shift register circuit group 11′ in the related art shown in FIG. 1 are split into multiple shift register circuit groups 11, while the signal lines 12′ that originally drive the shift register circuit group 11′ are also split into multiple signal line groups 131, so that the number of signal lines 13 electrically connected to each shift register circuit group 11 in this embodiment is reduced, thereby effectively reducing the arrangement density of the signal lines 13 in the vicinity of each shift register circuit group 11. For example, if the first scan signal is the sweep signal SWEEP′, the signal lines 12′ include multiple sweep clock signal lines SWEEP_IN′. Exemplarily, six sweep clock signal lines SWEEP_IN′ (SWEEP_IN′1 to SWEEP_IN′6) are provided, and the six sweep clock signal lines SWEEP_IN′ are disposed next to the shift register circuit group 11′, and the distance between the sweep clock signal line SWEEP_IN′ and the shift register circuit group 11′ is relatively close, which leads to excessive concentration of the sweep clock signal lines SWEEP_IN′ and thus is not conducive to wiring. In this embodiment, if six sweep clock signal lines SWEEP_IN (SWEEP_IN1 to SWEEP_IN6) are similarly provided, less than six sweep clock signal lines are disposed in the vicinity of each shift register circuit group 11, thereby effectively reducing the arrangement density of the signal lines 13 in the vicinity of each shift register circuit group 11, avoiding the problem of uniform display of the display image of the display panel due to the difference of the wiring, and improving the effect of the image display. In addition, the signal lines 13 of the display panel with the frameless design need to pass through the frame of the display region AA and then be transmitted to the side of the substrate 10 facing away from the circuit structure layer in a manner of being routed as a backline; therefore, in this embodiment, the arrangement density of the signal lines 13 is reduced, the difficulty of the back-routing process is improved, and the preparation efficiency of the display panel and the qualified rate of the finished product are improved.

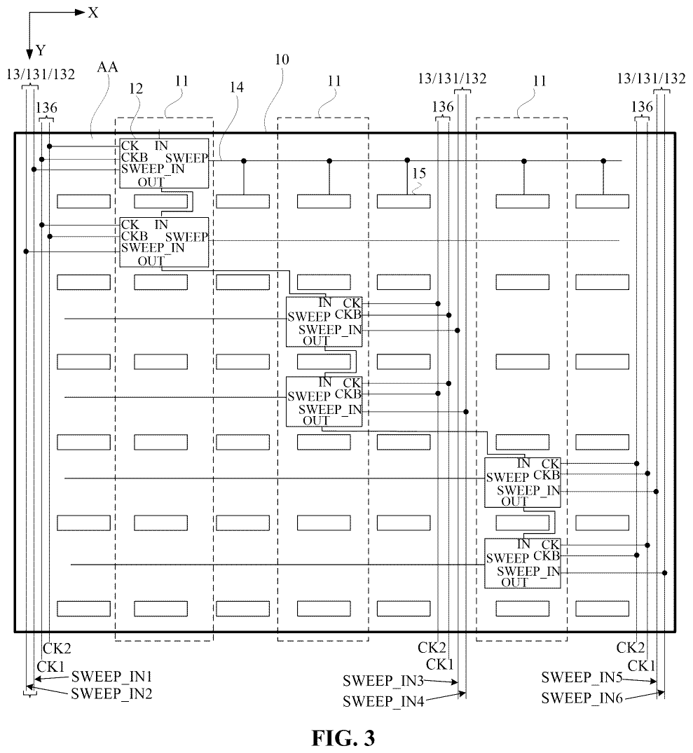

FIG. 3 is a schematic structural diagram of another display panel according to an embodiment of the present disclosure. Referring to FIGS. 2 and 3, in one or more embodiments, the signal line groups 131 may be disposed in one-to-one correspondence with the shift register circuit groups 11, and the signal line group 131 is electrically connected to a corresponding shift register circuit group 11. In this embodiment, the number of signal line groups 131 may be the same as the number of shift register circuit groups 11, and each signal line group 131 is electrically connected to the corresponding shift register circuit group 11 in one-to-one correspondence. As shown in FIG. 2, two signal line groups 131 and two shift register circuit groups 11 are provided, if six sweep clock signal lines SWEEP_IN (SWEEP_IN1 to SWEEP_IN6) are provided on the entire display panel, one signal line group 131 may include three sweep clock signal lines SWEEP_IN (such as SWEEP_IN1, SWEEP_IN3, and SWEEP_IN5), and the other signal line group 131 may include three sweep clock signal lines SWEEP_IN (such as SWEEP_IN2, SWEEP_IN4, and SWEEP_IN6). Alternatively, as shown in FIG. 3, when three signal line groups 131 and three shift register circuit groups 11 are provided, one signal line group 131 may include two sweep clock signal lines SWEEP_IN (such as SWEEP_IN1 and SWEEP_IN2), another signal line group 131 may include two sweep clock signal lines SWEEP_IN (such as SWEEP_IN3 and SWEEP_IN4), and the last signal line group 131 may include two sweep clock signal lines SWEEP_IN (such as SWEEP_IN5 and SWEEP_IN6). In this embodiment, one cascaded shift register circuit group in the related art is split into multiple shift register circuit groups 11, and the required signal lines 13 are dispersedly disposed, so that the number of signal lines 13 electrically connected to each shift register circuit group 11 is reduced, the arrangement density of the signal lines 13 is reduced, and the difficulty of wiring process and back-routing process of the display panel is reduced.

With continued reference to FIGS. 2 and 3, in one or more embodiments, the display region AA may include M shift register circuit groups 11, and M is an integer greater than 1. The signal lines 13 may include N first signal lines 132. The N first signal lines 132 are divided into M signal line groups 131, where N>M, and N is an integer. FIG. 2 is illustrated with M=2 as an example, and FIG. 3 is illustrated with M=3 as an example. The display region AA may include M shift register circuit groups 11. In this embodiment, an example in which the first signal line 132 is the sweep clock signal line SWEEP_IN is used for illustration; however, in this embodiment, the first signal line 132 may be the sweep clock signal line SWEEP_IN or other signal lines densely disposed. In this embodiment, the entire display panel requires the N first signal lines 132. Exemplarily, as shown in FIG. 4, FIG. 4 is a timing diagram of a sweep clock signal line according to an embodiment of the present disclosure. The sweep clock signal line SWEEP_IN may include a total of six sweep clock signal lines including SWEEP_IN1 to SWEEP_IN6, and a time difference between adjacent sweep clock signal lines is one row time H, that is, a single row time, where H=1/(P×f1), f1 is the refresh frequency of the display panel, and P is the number of rows of the pixel circuits of the display panel. As shown in FIG. 2, the six first signal lines 132 may be divided into two signal line groups 131. As shown in FIG. 3, the six first signal lines 132 may be divided into three signal line groups 131. In this embodiment, the N first signal lines 132 centrally disposed next to one shift register circuit group in the related art are divided into M signal line groups 131, and one cascaded shift register circuit group in the related art is divided into M shift register circuit groups 11, that is, the signal line group 131 is electrically connected only to the shift register circuit group 11 corresponding to the signal line group 131 and may be disposed in the vicinity of the shift register circuit group 11 electrically connected to the signal line group 131, thereby effectively dispersing the arrangement density of the first signal lines 132 and reducing the difficulty of the wiring process. Exemplarily, in the related art, if one shift register circuit group includes L shift register units 12 in the first direction Y, to enable each shift register unit 12 electrically connected to a corresponding row of pixel circuits to provide the first scan signal for the row of pixel circuits, then the split M shift register circuit groups 11 may include a total of P shift register units 12 to ensure that each row of pixel circuits can acquire the corresponding first scan signal. In one or more embodiments, different shift register circuit groups 11 do not overlap in the first direction Y. Referring to FIGS. 2 and 3, the shift register circuit groups 11 extend in the first direction Y, specifically, each shift register circuit group 11 includes multiple shift register units 12 arranged in the first direction Y, and no overlap exists between different shift register circuit groups 11 in the first direction Y, that is, no overlap exists between the shift register units 12 of different shift register circuit groups 11.

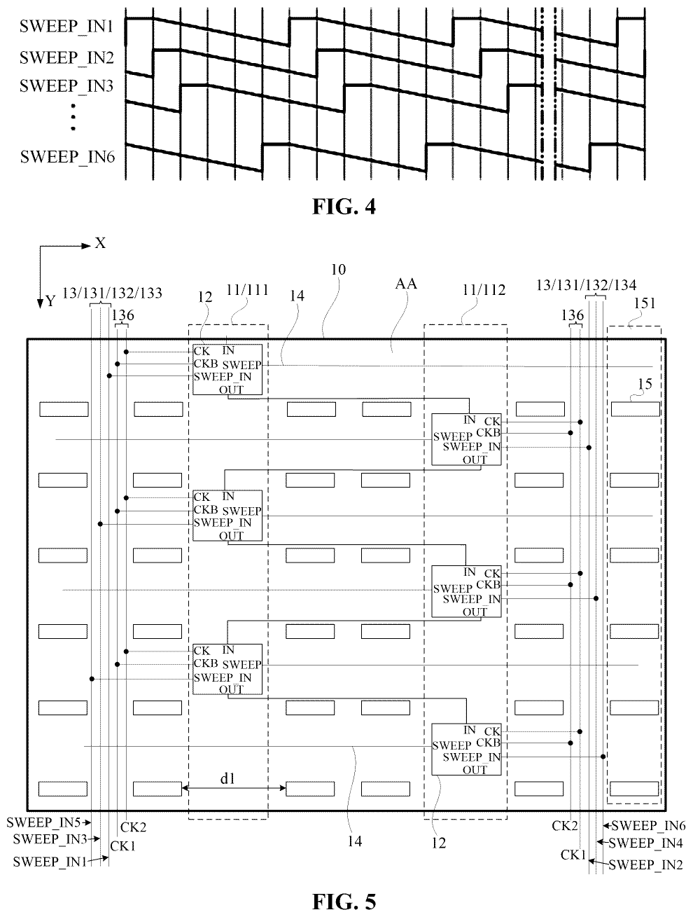

FIG. 5 is a schematic structural diagram of another display panel according to an embodiment of the present disclosure. In one or more embodiments, the display region AA may include multiple pixel circuits 15. The multiple pixel circuits 15 are arranged in the first direction Y to form pixel circuit columns 151. Multiple pixel circuit columns 151 are sequentially arranged in the second direction X. The shift register circuit group 11 is disposed in a first spacing region d1 between two adjacent pixel circuit columns 151. In addition to the shift register circuit groups 11, the circuit structure layer is further provided with pixel circuits 15 arranged in an array. In this embodiment, multiple pixel circuit columns 151 extending in the first direction Y may be included, and the multiple pixel circuit columns 151 are sequentially arranged in the second direction X. As shown in FIG. 5, the shift register circuit group 11 may be disposed in the first spacing region d1 between two adjacent pixel circuit columns 151. Of course, in one or more embodiments, the display region AA includes multiple pixel circuits 15, and the multiple pixel circuits 15 may be arranged in the second direction X to form pixel circuit rows 152. Multiple pixel circuit rows 152 are sequentially arranged in the first direction Y. As shown in FIG. 2, the shift register units 12 in the shift register circuit group 11 may be disposed in a second spacing region d2 between two adjacent pixel circuit rows 152. In this embodiment, the shift register circuit group 11 may be disposed in the first spacing region d1 between two adjacent pixel circuit columns 151 or in the second spacing region d2 between two adjacent pixel circuit rows 152, and the specific position of the shift register circuit group 11 is not limited in this embodiment. Moreover, the shift register units 12 in the shift register circuit group 11 may be flexibly set according to the spatial layout of the circuit structure layer, to avoid the situation where the wires are too dense in part of the regions of the circuit structure, and further increase the process difficulty of the display panel.

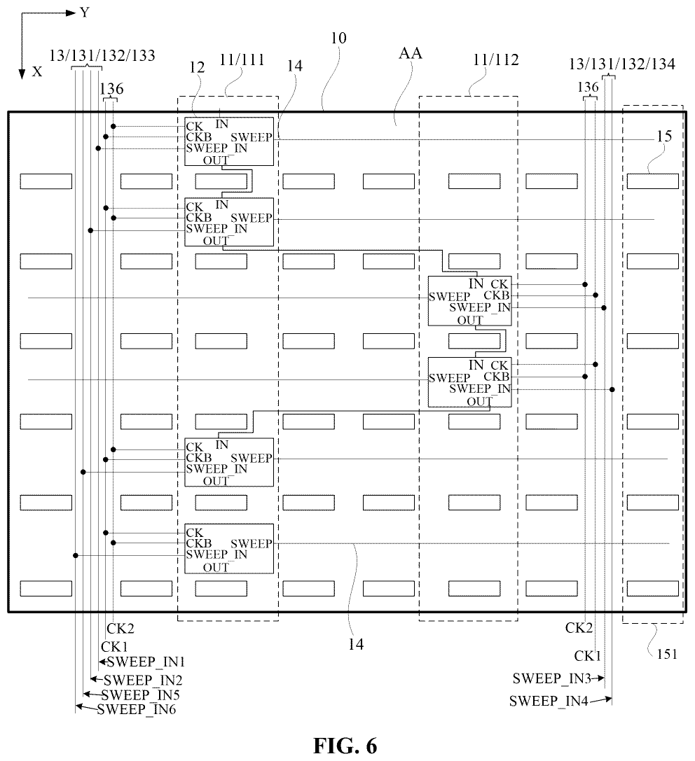

FIG. 6 is a schematic structural diagram of another display panel according to an embodiment of the present disclosure. With continued reference to FIGS. 2 and 6, in one or more embodiments, the N first signal lines 132 may include a first signal line group 133 and a second signal line group 134. The first signal line group 133 includes R first signal lines 132. The second signal line group 134 includes (N−R) first signal lines 132. The first signal line group 133 is electrically connected to the first shift register circuit group 111, and the second signal line group 134 is electrically connected to the second shift register circuit group 112, where N>R, and R is an integer.

In this embodiment, the N first signal lines 132 may be divided into the first signal line group 133 and the second signal line group 134, and the shift register circuit groups in this embodiment may include only the first shift register circuit group 111 and the second shift register circuit group 112. The first signal line group 133 is electrically connected to the first shift register circuit group 111, to provide a drive signal for the first shift register circuit group 111. The second signal line group 134 is electrically connected to the second shift register circuit group 112, to provide a drive signal for the second shift register circuit group 112. The signal lines 13 include N first signal lines 132, a part (R first signal lines 132) of the N first signal lines 132 constitutes the first signal line group 133, and the remaining part ((N−R) first signal lines 132) of the N first signal lines 132 constitutes the second signal line group 134. Referring to FIGS. 2 and 4, R and (N−R) may have the same value, for example, both R and (N−R) are 3. Of course, R and (N−R) may have different values. Referring to FIG. 6, R is 4, and (N−R) is 2. In this embodiment, the N first signal lines 132 are divided into two parts, and these two parts of the first signal lines 132 are respectively connected to different shift register circuit groups 11, to avoid the situation of the dense wires caused by connecting the N first signal lines 132 to the same shift register circuit group. In this embodiment, the first signal lines 132 are effectively dispersed, the wire density of the signal lines is reduced, the difficulty of the wiring process and the back-routing process is reduced, and the reliability of the display panel is improved.

It is to be noted that, in one or more embodiments, as shown in FIGS. 2 to 6, the display region AA may include multiple pixel circuits 15. The multiple pixel circuits 15 are arranged in the first direction Y to form the pixel circuit columns 151. The multiple pixel circuit columns 151 are sequentially arranged in the second direction X. The first shift register circuit group 111 and the second shift register circuit group 112 are spaced by f pixel circuit columns 151. In this embodiment, to further disperse the first signal line group 133 and the second signal line group 134, the first shift register circuit group 111 and the second shift register circuit group 112 may be controlled to be spaced by the f pixel circuit columns 151, where f may be an integer greater than or equal to 2, to enable the spacing between the first shift register circuit group 111 and the second shift register circuit group 112 to be greater than the spacing d3 between two pixels (the spacing between centers of two pixel circuits 15), so that the spacing between the first signal line group 133 and the second signal line group 134 is greater than the spacing d3 between the two pixels, whereby the first signal lines 132 are further dispersed, the wire density of the first signal lines 132, and the wiring process is simplified. On the basis of the above embodiments, f may be an integer greater than or equal to 4, the number of signals in the local region is controlled to be reduced or halved, and the signal lines 13 required by the shift register circuit group 11 are further dispersed, so that the density of the signal lines 13 is reduced.

With continued reference to FIG. 2, the shift register circuit group 11 includes the first shift register circuit group 111 and the second shift register circuit group 112. In one or more embodiments, the display region AA may include multiple pixel circuits 15. The multiple pixel circuits 15 are arranged in the second direction X to form pixel circuit rows 152. Multiple pixel circuit rows 152 are sequentially arranged in the first direction Y. The pixel circuit rows 152 are electrically connected to the shift register units 12. The shift register unit 12 is a first shift register unit 121 or a second shift register unit 122. The shift register unit 12 is disposed in the second spacing region d2 between two adjacent pixel circuit rows 152. In this embodiment, the pixel circuit rows 152 are electrically connected to the first scan signal lines 14 in one-to-one correspondence, and the shift register units 12 are electrically connected to the first scan signal lines 14 in one-to-one correspondence. The shift register unit 12 is the first shift register unit 121 or the second shift register unit 122. Exemplarily, as shown in FIG. 2, a shift register unit 12 electrically connected to the first pixel circuit row 152 is the first shift register unit 121, a shift register unit 12 electrically connected to the second pixel circuit row 152 is the second shift register unit 122, and the shift register units 12 corresponding to two adjacent pixel circuit rows 152 are connected in cascade to achieve line-by-line scanning of the pixel circuit rows 152 of the entire display panel. In this embodiment, to facilitate the cascading between the first shift register unit 121 and the second shift register unit 122, the shift register units 12 may be disposed in the second spacing region d2 between two adjacent pixel circuit rows 152.

With continued reference to FIG. 2, in one or more embodiments, in the first direction Y, the shift register unit 12 between an i-th pixel circuit row 152 and an (i+1)-th pixel circuit row 152 is electrically connected to the shift register unit 12 between the (i+1)-th pixel circuit row 152 and an (i+2)-th pixel circuit row 152 through a first cascade wire 16, where i is a positive integer, i≤P−2, and P is the total number of pixel circuit rows 152. In this embodiment, the shift register unit 12 electrically connected to the (i+1)-th pixel circuit row 152 may be disposed between the i-th pixel circuit row 152 and the (i+1)-th pixel circuit row 152, and the shift register unit 12 may be the first shift register unit 121. The shift register unit 12 electrically connected to the (i+2)-th pixel circuit row 152 may be disposed between the (i+1)-th pixel circuit row 152 and the (i+2)-th pixel circuit row 152, and the shift register unit 12 may be the second shift register unit 122. Thus, the first shift register unit 121 and the second shift register unit 122 are electrically connected through the first cascade wire 16. In this embodiment, the shift register units 12 electrically connected to two adjacent pixel circuit rows 152 belong to different shift register circuit groups 11, respectively. Exemplarily, the shift register units 12 electrically connected to the odd-numbered pixel circuit rows 152 may be the first shift register units 121 and are located in the first shift register circuit group 111; the shift register units 12 electrically connected to the even-numbered pixel circuit rows 152 may be the second shift register units 122 and are located in the second shift register circuit group 112, and every adjacent two pixel circuit rows 152 are electrically connected through the first cascade wire 16. In this embodiment, the first cascade wire 16 may be uniformly disposed in the entire display region AA, thereby improving the display uniformity of the display region AA and improving the effect of the image display. It is to be noted that the shift register units 12 electrically connected to two adjacent pixel circuit rows 152 may both be the first shift register units 121 or the second shift register units 122. Referring to FIG. 6, the shift register unit 12 electrically connected to the 1st pixel circuit row 152 and the shift register unit 12 electrically connected to the 2nd pixel circuit row 152 are both the first shift register units 121, and the shift register unit 12 electrically connected to the 3rd pixel circuit row 152 and the shift register unit 12 electrically connected to the 4th pixel circuit row 152 are both the second shift register units 122. Then, the first shift register unit 121 electrically connected to the 2nd pixel circuit row 152 is electrically connected to the second shift register unit 122 electrically connected to the 3rd pixel circuit row 152 through the first cascade wire 16. In this embodiment, only when the shift register units 12 electrically connected to two adjacent pixel circuit rows 15 belong to different shift register circuit groups 11, respectively, the cascade of the two shift register units 12 is achieved through the first cascade wire 16. The shift register circuit group 11 to which the P shift register units 12 belong is not particularly limited in this embodiment.

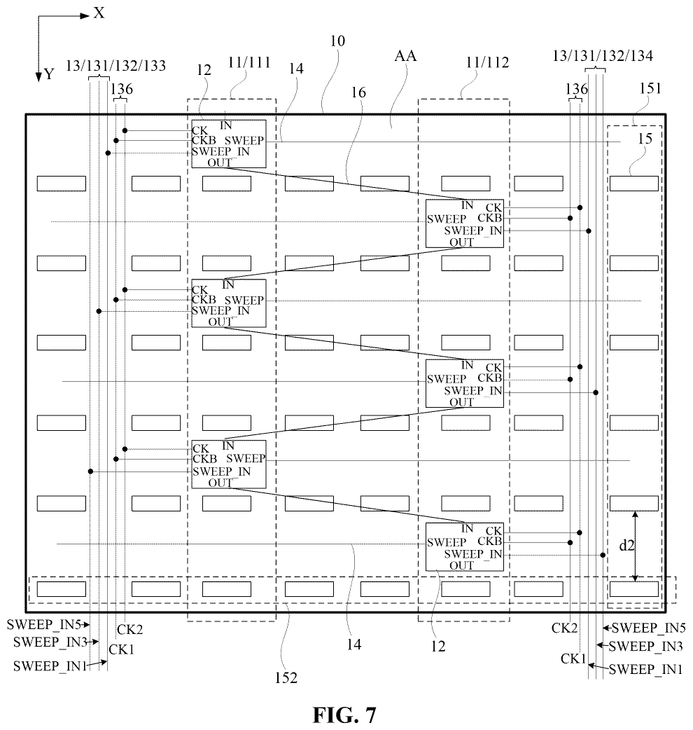

FIG. 7 is a schematic structural diagram of another display panel according to an embodiment of the present disclosure. In one or more embodiments, in the direction perpendicular to the substrate 10, the first cascade wire 16 overlaps with the (i+1)-th pixel circuit row 152. The first shift register circuit group 111 and the second shift register circuit group 112 are sequentially arranged in the second direction X, the first cascade wire 16 tends to extend in the second direction X. In this embodiment, when the shift register unit 12 between the i-th pixel circuit row 152 and the (i+1)-th pixel circuit row 152 is electrically connected to the shift register unit 12 between the (i+1)-th pixel circuit row 152 and the (i+2)-th pixel circuit row 152 through the first cascade wire 16, and an overlap may exist between the first cascade wire 16 and the (i+1)-th pixel circuit row 152. Exemplarily, as shown in FIG. 7, the first cascade wire 16 may be of a linear type, and the overlapping region exists between the first cascade wire 16 and part of the pixel circuits 15 in the (i+1)-th pixel circuit row 152. It is to be noted that when an overlapping region exists between the first cascade wire 16 and the (i+1)-th pixel circuit row 152, the first cascade wire 16 is not disposed in the same layer as the pixel circuits 15, and an insulating layer needs to be disposed between the first cascade wire 16 and the pixel circuits 15 to avoid short circuit between the first cascade wire 16 and the pixel circuits 15.

Of course, referring to FIG. 2, to further reduce the parasitic capacitance between the first cascade wire 16 and the pixel circuits 15, the first cascade wire 16 and the pixel circuits 15 may not overlap, that is, no overlapping area exists between the first cascade wire 16 and the pixel circuits 15 in the plane parallel to the substrate 10, thereby avoiding the influence of the parasitic capacitance on the cascade signal between the shift register units 12, improving the accuracy of the first scan signal output by the shift register units 12, and further improving the effect of the image display.

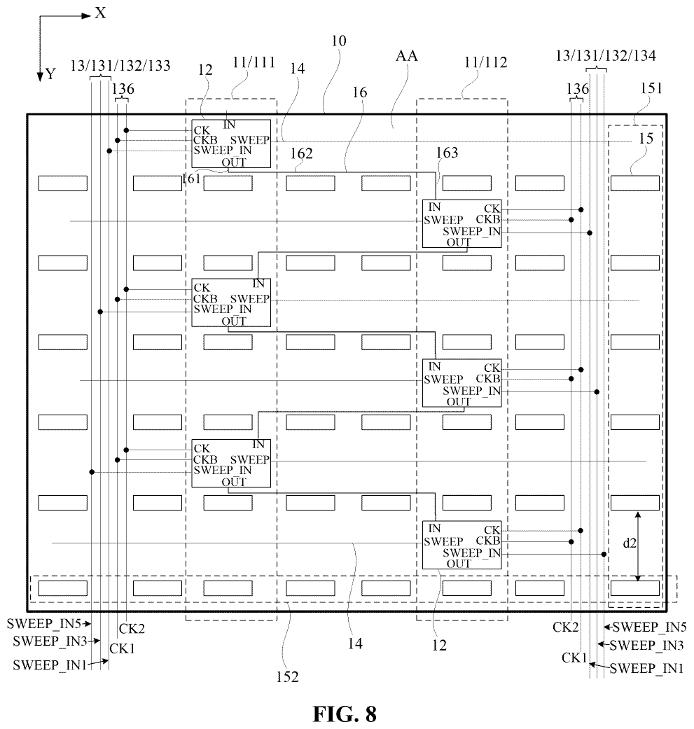

FIG. 8 is a schematic structural diagram of another display panel according to an embodiment of the present disclosure. In one or more embodiments, the first cascade wire 16 may include a first branch portion 161 extending in the first direction Y, a second branch portion 162 extending in the second direction X, and a third branch portion 163 extending in the first direction Y. The first branch portion 161, the second branch portion 162 and the third branch portion 163 are electrically connected in sequence. In the direction perpendicular to the substrate 10, the first cascade wire 16 does not overlap with the pixel circuits 15. As shown in FIG. 8, in this embodiment, the first cascade wire 16 may have a folded line shape and includes the first branch portion 161, the second branch portion 162, and the third branch portion 163 connected in sequence. The first branch portion 161 and the third branch portion 163 extend in the first direction Y, and the second branch portion 162 extends in the second direction X, thereby forming the folded line shape. In this embodiment, the first branch portion 161, the second branch portion 162 and the third branch portion 163 are all disposed in the gap region between pixel circuits 15, thereby reducing the parasitic capacitance between the first cascade wire 16 and the pixel circuits 15, improving the accuracy of the first scan signal output by the shift register units 12, and further improving the effect of the image display.

In one or more embodiments, in the first direction Y, the shift register unit 12 connected to the i-th pixel circuit row 152 may be the first shift register unit 121. The shift register unit 12 connected to the (i+1)-th pixel circuit row 152 may be the second shift register unit 122. The first signal line group 133 may include a k-th first signal line 132 among the N first signal lines 132. The second signal line group 134 includes a (k+1)-th first signal line 132 among the N first signal lines 132. A k-th first signal line 132 in the first signal line group 133 is electrically connected to the first shift register unit 121. A (k+1)-th first signal line 132 in the second signal line group 134 is electrically connected to the second shift register unit 122, where each of k and j is an integer greater than zero.

As can be seen from the above embodiments, the display panel includes N first signal lines 132 disposed sequentially, and the timing of effective pulses between two adjacent first signal lines 132 differs by one row time. Referring to FIG. 2, in the shift register units 12 electrically connected to two adjacent pixel circuit rows 15, one shift register unit is the first shift register unit 121, and the other shift register unit is the second shift register unit 122. A k-th first signal line 132 among the N first signal lines 132 is located in the first signal line group 133, and a (k+1)-th first signal line 132 among the N first signal lines 132 is located in the second signal line group 134. Exemplarily, the shift register unit 12 connected to the 1st pixel circuit row 152 may be the first shift register unit 121, the shift register unit 12 connected to the 2nd pixel circuit row 152 may be the second shift register unit 122, the shift register unit 12 connected to the 3rd pixel circuit row 152 may be the first shift register unit 121, the shift register unit 12 connected to the 4th pixel circuit row 152 may be the second shift register unit 122, the shift register unit 12 connected to the 5th pixel circuit row 152 may be the first shift register unit 122, and the shift register unit 12 connected to the 6th pixel circuit row 152 may be the second shift register unit 122. The 1st first signal line 132, the 3rd first signal line 132, and the 5th first signal line 132 (SWEEP_IN1, SWEEP_IN3, and SWEEP_IN5) among the six first signal lines 132 are located in the first signal line group 133, and the 2nd first signal line 132, the 4th first signal line 132, and the 6th first signal line 132 (SWEEP_IN2, SWEEP_IN4, and SWEEP_IN6) among the six first signal lines 132 are located in the second signal line group 134. The first shift register unit 121 connected to the 1st pixel circuit row 152 is accessed to SWEEP_IN1, the second shift register unit 122 connected to the 2nd pixel circuit row 152 is accessed to SWEEP_IN2, the first shift register unit 121 connected to the 3rd pixel circuit row 152 is accessed to SWEEP_IN3, the second shift register unit 122 connected to the 4th pixel circuit row 152 is accessed to SWEEP_IN4, the first shift register unit 121 connected to the 5th pixel circuit row 152 is accessed to SWEEP_IN5, the second shift register unit 122 connected to the 6th pixel circuit row 152 is accessed to SWEEP_IN6, the first shift register unit 121 connected to the 7th pixel circuit row 152 is accessed to SWEEP_IN1, the second shift register unit 122 connected to the 8th pixel circuit row 152 is accessed to SWEEP_IN2, by analogy, the second shift register unit 122 connected to the 12th pixel circuit row 152 is accessed to SWEEP_IN6. In this embodiment, the dispersed first signal line group 133 and second signal line group 134 may also satisfy the drive requirements of the entire display panel, whereby the arrangement density of the signal lines 13 is reduced, the difficulty of the back-routing process is improved, and the preparation efficiency of the display panel and the qualified rate of the finished product are improved.

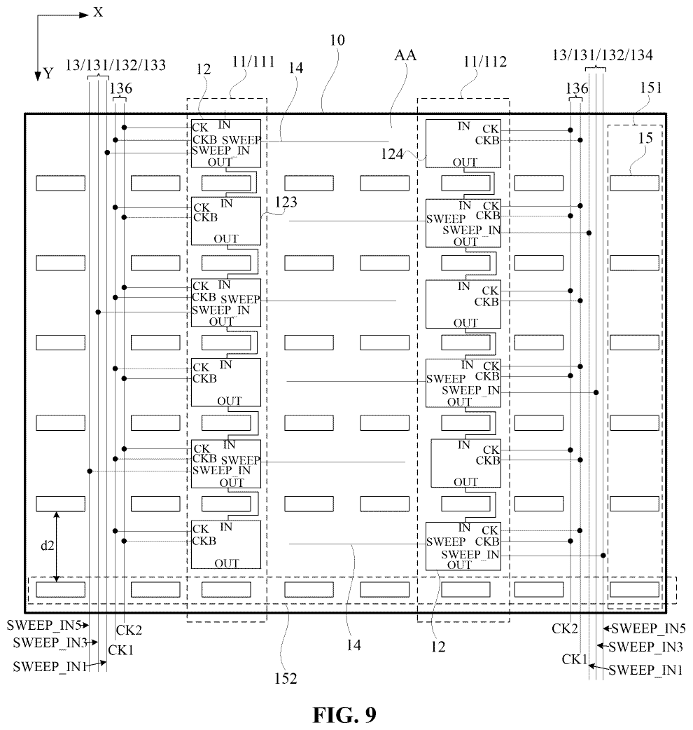

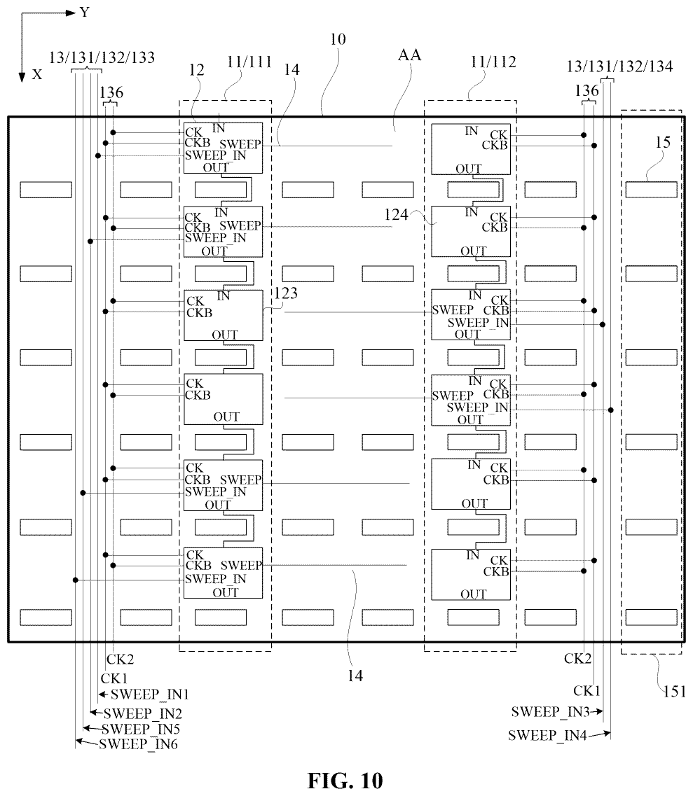

FIG. 9 is a schematic structural diagram of another display panel according to an embodiment of the present disclosure. FIG. 10 is a schematic structural diagram of another display panel according to an embodiment of the present disclosure. In one or more embodiments, the first shift register circuit group 111 may further include a first auxiliary shift register unit 123. The second shift register circuit group 112 further includes a second auxiliary shift register unit 124. In the first direction Y, two adjacent first shift register units 121 are connected in cascade through at least one first auxiliary shift register unit 123. In the first direction Y, two adjacent second shift register units 122 are connected in cascade through at least one second auxiliary shift register unit 124. In this manner, the cascading between the first shift register units 121 of the first shift register circuit group 111 and the second shift register units 122 of the second shift register circuit group 112 can be avoided, and thus the voltage drop caused by the first cascade wire 16 is reduced. It is to be noted that the first scan signal lines 14 in FIGS. 9 and 10 do not extend to the entire display region AA to show the auxiliary shift register units, but in practical applications, the first scan signal lines 14 need to be connected to the entire row of pixel circuits 15 and need to be extended to the entire display region AA in the second direction X. In this embodiment, the cascading between two adjacent first shift register units 121 is achieved through at least one first auxiliary shift register unit 123, and the cascading between two adjacent second shift register units 122 is achieved through at least one second auxiliary shift register unit 124. For example, as shown in FIG. 10, two adjacent first shift register units 121 are connected in cascade through two first auxiliary shift register units 123, and two adjacent second shift register units 122 are connected in cascade through two second auxiliary shift register units 124. In this embodiment, the auxiliary shift register unit only serves as a shift unit between two adjacent shift register units, and it does not need to be accessed to the shift register unit, nor does it need to be electrically connected to the first scan signal line to output the first scan signal. In other words, the auxiliary shift register unit functions as a device to assist the operation of the above-described shift register units and cannot output the scan signal for driving the pixel circuit 15. As shown in FIG. 9, two adjacent first shift register units 121 are connected in cascade through one first auxiliary shift register unit 123, and two adjacent second shift register units 122 are connected in cascade through one second auxiliary shift register unit 124. In this embodiment, not only the idle second spacing region d2 between two adjacent pixel circuit rows 152 between pixel circuits 15 is utilized, but also the setting of the longer first cascade wire 16 is avoided, and it is only necessary to provide the cascade wire between the shift register unit and the auxiliary shift register unit, which can effectively prevent the voltage drop of the cascade signal. In addition, the cascade signal between two adjacent first shift register units 121 is strengthened via the first auxiliary shift register unit 123 so that the input signal of the shift register unit 12 is more stable, and the image display effect of the display panel is improved.

With continued reference to FIGS. 9 and 10, in one or more embodiments, the first shift register unit 121 and the second auxiliary shift register unit 124 may be located between a t-th pixel circuit row 152 and a (t+1)-th pixel circuit row 152, and the second shift register unit 122 and the first auxiliary shift register unit 123 are located between the (t+1)-th pixel circuit row 152 and a (t+2)-th pixel circuit row 152, where 1 St≤P−2, and P is the total number of pixel circuit rows 152. In the second spacing region d2 between two adjacent pixel circuit rows 152, both the first shift register unit 121 and the second auxiliary shift register unit 124 may be disposed, or both the second shift register unit 122 and the first auxiliary shift register unit 123 may be disposed. In other words, in the second direction X, the first shift register unit 121 overlaps with the second auxiliary shift register unit 124, and the second shift register unit 122 overlaps with the first auxiliary shift register unit 123. Therefore, it can be seen from this that in the second spacing region d2 between two adjacent pixel circuit rows 152, only one shift register unit (either the first shift register unit 121 or the second shift register unit 122) is configured to output the first scan signal, and the auxiliary shift register unit is only configured to achieve the cascading, thereby enhancing the stability of cascading signals between adjacent shift register units. It is to be noted that in this embodiment, the auxiliary shift register unit only has the function of cascaded displacement and no longer outputs the first scan signal, such as the sweep signal.

Referring to FIG. 9, in one or more embodiments, in the first direction Y, the shift register unit 12 connected to the i-th pixel circuit row 152 may be the first shift register unit 121, and the shift register unit 12 connected to the (i+1)-th pixel circuit row 152 may be the second shift register unit 122, where i is an integer greater than zero. In the first direction Y, two adjacent first shift register units 121 are connected in cascade through the first auxiliary shift register unit 123. In the first direction Y, two adjacent second shift register units 122 are connected in cascade through the second auxiliary shift register unit 124. In this embodiment, in the first shift register circuit group 111, the first shift register units 121 and the first auxiliary shift register units 123 are alternately disposed in the first direction Y. In the second shift register circuit group 112, the second shift register units 122 and the second auxiliary shift register units 124 are alternately arranged in the first direction Y. If the shift register units 12 in each shift register circuit group 11 are disposed in every other row, half of the second spacing regions d2 between the pixel circuit rows 152 is left vacant. In this embodiment, the auxiliary shift register units are disposed in the vacant second spacing regions d2, thereby achieving a more uniform layout of the circuit structure layer and improving the uniformity of image display. Moreover, the auxiliary shift register unit effectively enhances the cascade signal, thereby improving the accuracy of the first scan signal.

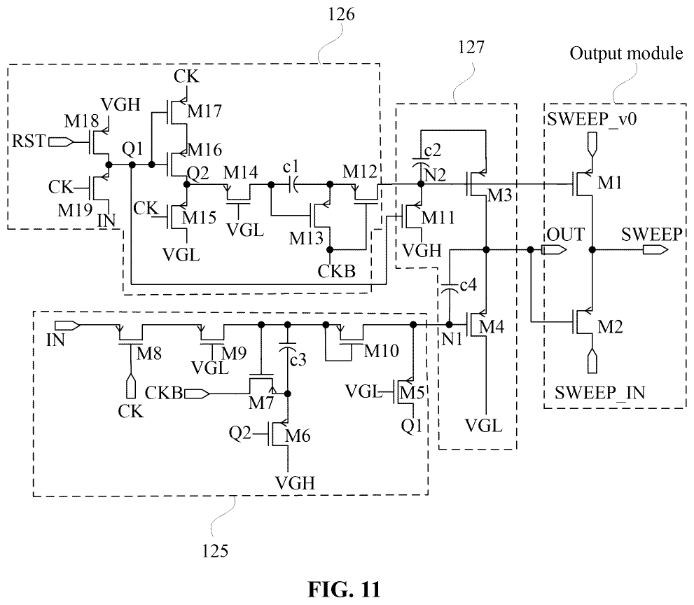

FIG. 11 is a schematic structural diagram of an auxiliary shift register unit according to an embodiment of the present disclosure. In one or more embodiments, each of the first auxiliary shift register unit 123 and the second auxiliary shift register unit 124 may include a first control module 125, a second control module 126, and a lower-level trigger module 127. The first control module 125 is electrically connected to a signal input terminal IN, a first clock terminal CK, a second clock terminal CKB, a first level terminal VGH, and a second level terminal VGL, separately, and the first control module 125 is electrically connected to the lower-level trigger module 127 at a first node N1, to control the potential of the first node N1. The second control module 126 is electrically connected to a reset terminal RST, the signal input terminal IN, the first clock terminal CK, the second clock terminal CKB, the first level terminal VGH, and the second level terminal VGL, separately, and the second control module 126 is electrically connected to the lower-level trigger module 127 at a second node N2, to control the potential of the second node N2. The lower-level trigger module 127 is configured to control a cascade signal terminal OUT to output a trigger signal according to the potential of the first node N1 and the potential of the second node N2. In this embodiment, the first control module 125 can control the potential of the first node N1, and the second control module 126 can control the potential of the second node N2. The lower-level trigger module 127 is configured to output the trigger signal (cascade signal) according to the potential of the first node N1 and the potential of the second node N2.

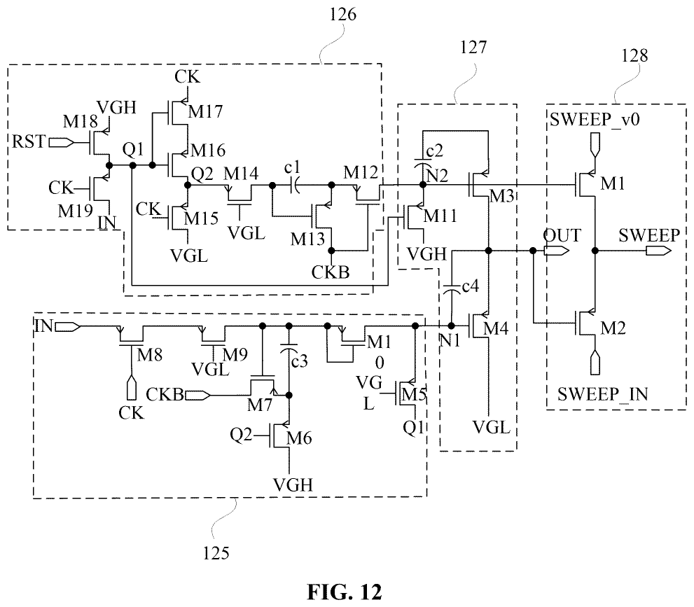

FIG. 12 is a schematic structural diagram of a shift register unit according to an embodiment of the present disclosure. In one or more embodiments, each of the first shift register unit 121 and the second shift register unit 122 may include a first control module 125, a second control module 126, a lower-level trigger module 127, and an output module 128. The first control module 125 is electrically connected to a signal input terminal IN, a first clock terminal CK, a second clock terminal CKB, a first level terminal VGH, and a second level terminal VGL, separately, and the first control module 125 is electrically connected to the lower-level trigger module 127 at a first node N1, to control the potential of the first node N1. The second control module 126 is electrically connected to a reset terminal RST, the signal input terminal IN, the first clock terminal CK, the second clock terminal CKB, the first level terminal VGH, and the second level terminal VGL, separately, and the second control module 126 is electrically connected to the lower-level trigger module 127 at a second node N2, to control the potential of the second node N2. The lower-level trigger module 127 is configured to control a cascade signal terminal OUT to output a trigger signal according to the potential of the first node N1 and the potential of the second node N2. The output module 128 is electrically connected to a third level terminal SWEEP_v0 and a sweep clock signal, separately, and the output module 128 outputs a sweep signal SWEEP according to the trigger signal. Referring to FIGS. 11 and 12, compared with the auxiliary shift register unit, the shift register unit further includes the output module 128, and the output module 128 is configured to output the sweep signal SWEEP according to the cascade signal terminal OUT, the third level terminal SWEEP_v0, and the sweep clock signal. Since the layout area of the display panel is limited, the transistor of the output module 128 needs to output the sweep signal SWEEP, and the sweep signal SWEEP needs to cross the multiple pixel circuits 15 in the second direction Y, so the transistor of the output module 128 has a large volume and will occupy more layout area. In this embodiment, the auxiliary shift register unit is not provided with the output module 128, which can reduce the layout area occupied by the auxiliary shift register unit. However, it is to be noted that the auxiliary shift register unit does not generate the scan signal and only shifts and transmits the trigger signal.

With continued reference to FIGS. 11 and 12, the lower-level trigger module 127 of the auxiliary shift register unit and the lower-level trigger module 127 of the shift register unit each include a third transistor M3, a fourth transistor M4, an eleventh transistor M11, a second capacitor c2, and a fourth capacitor c4. The first control module 125 includes a fifth transistor M5, a sixth transistor M6, a seventh transistor M7, an eighth transistor M8, a ninth transistor M9, a tenth transistor M10, and a third capacitor c3. The second control module 126 includes a twelfth transistor M12, a thirteenth transistor M13, a fourteenth transistor M14, a fifteenth transistor M15, a sixteenth transistor M16, a seventeenth transistor M17, an eighteenth transistor M18, a nineteenth transistor M19, and a first capacitor c1. A control terminal of the eighteenth transistor M18 is connected to the reset terminal, a first terminal of the eighteenth transistor M18 is connected to the first level terminal VGH, and a second terminal of the eighteenth transistor M18 is connected to a third node Q1, a first terminal of the nineteenth transistor M19, a control terminal of the seventeenth transistor M17, and a control terminal of the sixteenth transistor M16, separately. A control terminal of the nineteenth transistor M19 is connected to the first clock terminal CK, and a second terminal of the nineteenth transistor M19 is connected to the signal input terminal IN. A first terminal of the seventeenth transistor M17 is connected to the first clock terminal CK, and a second terminal of the seventeenth transistor M17 is connected to a first terminal of the sixteenth transistor M16. A second terminal of the sixteenth transistor M16 is connected to a fourth node Q2, a first terminal of the fifteenth transistor M15, and a first terminal of the fourteenth transistor M14, separately. A control terminal of the fifteenth transistor M15 is connected to the first clock terminal CK, and a second terminal of the fifteenth transistor M15 is connected to the second level terminal VGL. A control terminal of the fourteenth transistor M14 is connected to the second level terminal VGL, and a second terminal of the fourteenth transistor M14 is connected to a first electrode of the first capacitor c1 and a control terminal of the thirteenth transistor M13. A second electrode of the first capacitor c1 is connected to a first terminal of the thirteenth transistor M13 and a first terminal of the twelfth transistor M12, separately. A second terminal of the thirteenth transistor M13 is connected to the second clock terminal CKB. A control terminal of the twelfth transistor M12 is connected to the second clock terminal CKB, and a second terminal of the twelfth transistor M12 is connected to the second node N2. A control terminal of the eighth transistor M8 is connected to the first clock terminal CK, a first terminal of the eighth transistor M8 is connected to the signal input terminal IN, and a second terminal of the eighth transistor M8 is connected to a first terminal of the ninth transistor M9. A control terminal of the ninth transistor M9 is connected to the second level terminal VGL, a second segment of the ninth transistor M9 is connected to a control terminal of the seventh transistor M7, a first electrode of the third capacitor c3, a control terminal of the tenth transistor M10, and a first terminal of the tenth transistor M10, separately. A first terminal of the seventh transistor M7 is connected to the second clock terminal CKB, and a second terminal of the seventh transistor M7 is connected to a second electrode of the third capacitor c3 and a first terminal of the sixth transistor M6, separately. A control terminal of the sixth transistor M6 is connected to the fourth node Q2, and a second terminal of the sixth transistor M6 is connected to the first level terminal VGH. A second terminal of the tenth transistor M10 is connected to a first terminal of the fifth transistor M5 and the first node N1, separately. A control terminal of the fifth transistor M5 is connected to the second level terminal VGL, and a second terminal of the fifth transistor M5 is connected to the third node Q1. A control terminal of the eleventh transistor M11 is connected to the third node Q1, and a first terminal of the eleventh transistor M11 is connected to the second node N2, a first electrode of the second capacitor c2, and a control terminal of the third transistor M3, separately. A second terminal of the eleventh transistor M11 is connected to the electrode of the first level terminal VGH. A second electrode of the second capacitor c2 is connected to a first terminal of the third transistor M3. A second terminal of the third transistor M3 is connected to a first electrode of the fourth capacitor c4, a first terminal of the fourth transistor M4, and the cascade signal terminal OUT. The first electrode of the fourth capacitor c4 is connected to the first node N1 and a control terminal of the fourth transistor M4, separately. A second terminal of the fourth transistor M4 is connected to the second level terminal VGL.

The output module 128 unique to the shift register unit includes a first transistor M1 and a second transistor M2. A control terminal of the first transistor M1 is connected to the second node N2, a first terminal of the first transistor M1 is connected to the third level terminal SWEEP_v0, and a second terminal of the first transistor M1 is connected to a sweep signal terminal and a first terminal of the second transistor M2, separately. A control terminal of the second transistor M2 is connected to the cascade signal terminal OUT, and a second terminal of the second transistor M2 is connected to a sweep clock signal line SWEEP_IN. The first transistor M1 and the second transistor M2 have a large size, and the auxiliary shift register unit is formed without the first transistor M1 and the second transistor M2 so that the layout area occupied by the auxiliary shift register unit can be reduced, and the enhancement of the cascade signal can be achieved.

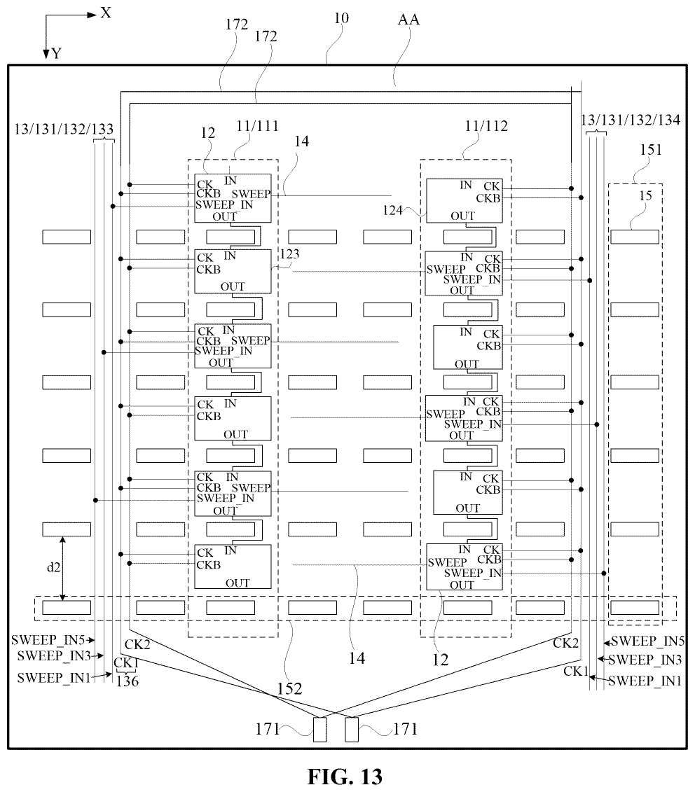

FIG. 13 is a schematic structural diagram of another display panel according to an embodiment of the present disclosure. In one or more embodiments, the display panel may further include first signal terminals 171. The first signal terminals 171 are electrically connected to signal lines 13 in the third signal line 136 in one-to-one correspondence. The first shift register circuit group 111 and the second shift register circuit group 112 share the first signal terminal 171. Common signals required by the first shift register circuit group 111 and the second shift register circuit group 112 may share one first signal terminal 171 to reduce the setting number of terminals. With continued reference to FIG. 13, in one or more embodiments, in the first direction Y, the first signal terminals 171 may be disposed on one side of the first shift register circuit group 111 or the second shift register circuit group 112, and the same signal line 13 in the third signal line 136 of the first shift register circuit group 111 and in the third signal line 136 of the second shift register circuit group 112 is electrically connected through a connection line 172. In the first direction Y, the connection line 172 is disposed on the side of the first shift register circuit group 111 or the second shift register circuit group 112 facing away from the first signal terminal 171. In the first direction Y, the first signal terminals 171 may be disposed on the side of the display region AA, that is, on the side of the first shift register circuit group 111 or the second shift register circuit group 112. To ensure that the same signal lines 13 in the third signal lines 136 for the two shift register circuit groups have the same potential, the connection line 172 may be disposed to connect the same signal line 13 so that the potential of the same signal line 13 tends to be stable, the control accuracy of the shift register circuit group is improved, and further the light-emitting effect of the display panel is improved. The connection line 172 is disposed on the side of the display region AA facing away from the first signal terminal 171 to facilitate achieving the electrical connection. Exemplarily, the first clock signal CK of the first shift register circuit group 111 and the first clock signal CK of the second shift register circuit group 112 may be connected through the connection line 172, and the second clock signal CKB of the first shift register circuit group 111 and the second clock signal CKB of the second shift register circuit group 112 may be connected through the connection line 172.

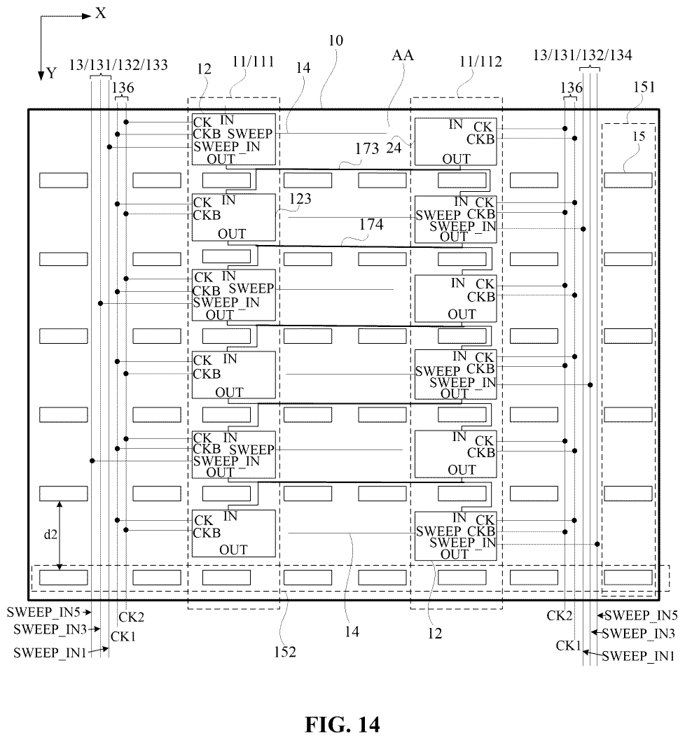

FIG. 14 is a schematic structural diagram of another display panel according to an embodiment of the present disclosure. In one or more embodiments, the first shift register unit 121, the first auxiliary shift register unit 123, the second shift register unit 122, and the second auxiliary shift register unit 124 may each include a cascade output terminal OUT. In the second direction X, cascade output terminals OUT of the first shift register unit 121 and the second auxiliary shift register unit 124 located between a t-th pixel circuit row 152 and a (t+1)-th pixel circuit row 152 are electrically connected through a first horizontal wire 173; and/or in the second direction, cascade output terminals OUT of the first auxiliary shift register unit 123 and the second shift register unit 122 located between the (t+1)-th pixel circuit row 152 and a (t+2)-th pixel circuit row 152 are electrically connected through a second horizontal wire 174. In the first direction Y, if the timings of the cascade signals of the first shift register unit 121 and the second auxiliary shift register unit 124 between the t-th pixel circuit row 152 and the (t+1)-th pixel circuit row 152 are the same, the cascade output terminal OUT of the first shift register unit 121 and the cascade output terminal OUT of the second auxiliary shift register unit 124 are electrically connected through the first horizontal wire 173. Similarly, in the first direction Y, the first auxiliary shift register unit 123 and the second shift register unit 122 between the (t+1)-th pixel circuit row 152 and the (t+2)-th pixel circuit row 152 have the same timing, and the cascade output terminal OUT of the first auxiliary shift register unit 123 and the cascade output terminal OUT of the second shift register unit 122 are electrically connected through the second horizontal wire 174. Cascade signals at the same stage are connected in parallel through the horizontal wire so that the cascade signals at the same stage can be further synchronized and the stability of the cascade signals can be enhanced.

With continued reference to FIG. 14, in one or more embodiments, in the second direction X, signal lines 13 electrically connected to the first shift register circuit group 111 may be located on the side of the first shift register circuit group 111 facing away from the second shift register circuit group 112. In the second direction X, signal lines 13 electrically connected to the second shift register circuit group 112 are located on the side of the second shift register circuit group 112 facing away from the first shift register circuit group 111. In the second direction X, the first shift register circuit group 111 and the second shift register circuit group 112 are disposed in sequence. The signal lines 13 electrically connected to the first shift register circuit group 111 may be located on the side of the first shift register circuit group 111 facing away from the second shift register circuit group 112. Similarly, the signal lines 13 electrically connected to the second shift register circuit group 112 may be located on the side of the second shift register circuit group 112 facing away from the first shift register circuit group 111. In this manner, the signal lines 13 can be dispersed and concentration of the signal lines 13 can be avoided. In this embodiment, the first signal line group 133 is electrically connected to the first shift register circuit group 111 and is disposed on the outer side of the first shift register circuit group 111 facing away from the second shift register circuit group 112. The second signal line group 134 is electrically connected to the second shift register circuit group 112 and is disposed on the outer side of the second shift register circuit group 112 facing away from the first shift register circuit group 111. In this embodiment, the wire density of the first signal lines 132 is halved, thereby dispersing the signal lines 13 required by the shift register circuit groups, and avoiding difficulties in back routing caused by excessive concentration of the signal lines.

In one or more embodiments, along the second direction X, at least part of the signal lines 13 electrically connected to the first shift register circuit group 111 may be disposed between the first shift register circuit group 111 and the second shift register circuit group 112; and/or, in the second direction X, at least part of the signal lines 13 electrically connected to the second shift register circuit group 112 may be disposed between the first shift register circuit group 111 and the second shift register circuit group 112. In this embodiment, the signal lines 13 may be disposed not only on the outer side of the first shift register circuit group 111 and the second shift register circuit group 112, but also at least partially disposed between the first shift register circuit group 111 and the second shift register circuit group 112. The signal lines 13 disposed between the first shift register circuit group 111 and the second shift register circuit group 112 may be the first signal lines 132 electrically connected to the first shift register circuit group 111, the first signal lines 132 electrically connected to the second shift register circuit group 112, or the signal lines 13 electrically connected to both the first shift register circuit group 111 and the second shift register circuit group 112, which is not particularly limited in this embodiment.

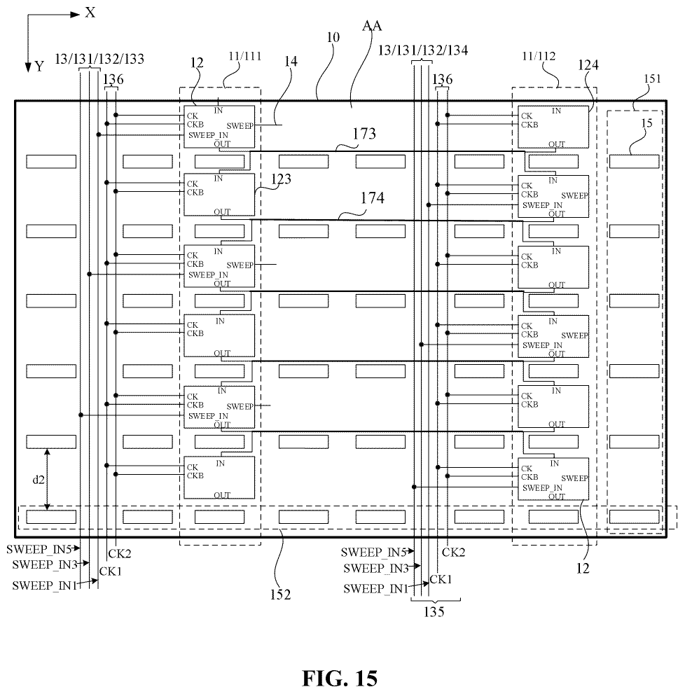

FIG. 15 is a schematic structural diagram of another display panel according to an embodiment of the present disclosure. As shown in FIG. 15, in one or more embodiments, the signal lines 13 disposed between the first shift register circuit group 111 and the second shift register circuit group 112 may be second signal lines 135. The first horizontal wire 173 and the second signal lines 135 are located in different film layers. The second horizontal wire 174 and the second signal lines 135 are located in different film layers. In this embodiment, the signal line 13 disposed between the first shift register circuit group 111 and the second shift register circuit group 112 may be referred to as the second signal line 135. The second signal line 135 may include the first signal line 132 or other signal lines, which is not particularly limited in this embodiment. If the second signal line 135 extends in the first direction Y, and the first horizontal wire 173 and the second horizontal wire 174 extend in the second direction X, the horizontal wire (the first horizontal wire 173 and the second horizontal wire 174) and the second signal line 135 intersect. In this embodiment, the second signal line 135 and the horizontal wire are respectively disposed in different film layers, thereby facilitating the wiring of the second signal line 135 and the horizontal wire, and improving the reliability of the display panel. Based on the above embodiments, in one or more embodiments, the signal lines 13 disposed between the first shift register circuit group 111 and the second shift register circuit group 112 may be the second signal lines 135. The second signal line 135, the first horizontal wire 173 and the second horizontal wire 174 are located in a first film layer. The first horizontal wire 173 and the second horizontal wire 174 are each provided with a cross-bridge, and the cross-bridge is disposed on a second film layer. In this embodiment, the horizontal wire (the first horizontal wire 173 and the second horizontal wire 174) and the second signal line 135 may also be located in the same film layer. Exemplarily, the horizontal wire and the second signal line 135 may be located in the first film layer, and either the horizontal wire or the second signal line 135 is interrupted at an intersection of the horizontal wire and the second signal line 135. At this time, the second film layer forms the cross-bridge to connect the interrupted horizontal wire or the interrupted second signal line 135 to enable them to transmit the corresponding signal. Regardless of the horizontal wire and the second signal line 135 disposed in different layers, or the horizontal wire and the second signal line 135 disposed in the same layer and provided with the cross-bridge, in this embodiment, the wiring of both the second signal lines 135 and the horizontal wires can be achieved between the first shift register circuit group 111 and the second shift register circuit group 112, and the reliability of the display panel can be improved.

In one or more embodiments, the signal lines 13 may further include third signal lines 136. The third signal line 136 includes a first clock signal line CK1, a second clock signal line CK2, a first level signal line V1, a second level signal line V2, and a start signal line STV. In FIG. 2, only an example in which the third signal line 136 includes the first clock signal line CK1 and the second clock signal line CK2 is used for illustration, but in practical applications, the third signal line 136 includes, but is not limited to, the first clock signal line CK1 (CK) and the second clock signal line CK2 (CKB). The third signal lines 136 are electrically connected to the shift register circuit groups 11 in one-to-one correspondence. Alternatively, the first shift register circuit group 111 and the second shift register circuit group 112 share the third signal line 136. The signal lines 13 disposed between the first shift register circuit group 111 and the second shift register circuit group 112 are the first clock signal lines CK and the second clock signal lines CKB. In this embodiment, each shift register circuit group 11 may be provided with a corresponding third signal line 136, or the first shift register circuit group 111 and the second shift register circuit group 112 may share the third signal line 136, and in this case, the third signal line 136 may be disposed between the first shift register circuit group 111 and the second shift register circuit group 112. Exemplarily, the first clock signal line CK and the second clock signal line CKB may be disposed between the first shift register circuit group 111 and the second shift register circuit group 112, thereby reducing the number of third signal lines 136 in the wiring and further reducing the process difficulty.

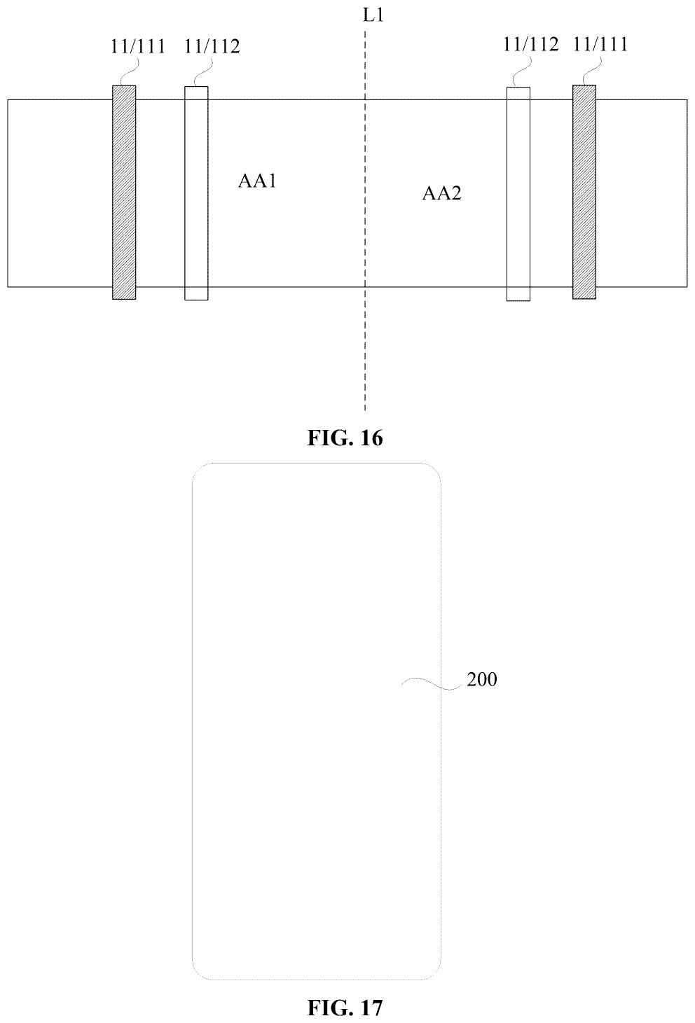

FIG. 16 is a schematic structural diagram of another display panel according to an embodiment of the present disclosure. In one or more embodiments, the display region AA may include a first display region AA1 and a second display region AA2. A first central axis L1 of the display region AA is located between the first display region AA1 and the second display region AA2. The first central axis L1 extends in the first direction Y. The first display region AA1 includes H1 first shift register circuit groups 111 and G1 second shift register circuit groups 112. The second display region AA2 includes H2 first shift register circuit groups 111 and G2 second shift register circuit groups 112. Each of H1, G1, H2 and G2 is a positive integer. It is to be noted that the first central axis L1 is not a line actually existing in the display region AA, but a virtual central axis artificially delineated by measurement, and the virtual central axis divides the display region AA into the first display region AA1 and the second display region AA2, to facilitate the explanation of the setting position of the shift register circuit group. The first central axis L1 equally divides the entire display region AA into two parts, that is, the first display region AA1 and the second display region AA2. In this embodiment, multiple first shift register circuit groups 111 and multiple second shift register circuit groups 112 may be provided. Exemplarily, H1 first shift register circuit groups 111 among the multiple first shift register circuit groups 111 are disposed in the first display region AA1, and H2 first shift register circuit groups 111 among the multiple first shift register circuit groups 111 are disposed in the second display region AA2. Similarly, G1 second shift register circuit groups 112 among the multiple second shift register circuit groups 112 are disposed in the first display region AA1, and G2 second shift register circuit groups 112 among the multiple second shift register circuit groups 112 are disposed in the second display region AA2. When the size of the display region AA in the second direction X is relatively large, the multiple first shift register circuit groups 111 and the multiple second shift register circuit groups 112 can increase the driving force to each row of pixel circuits so that the display effect of the display panel can be improved while effectively dispersing the wire density of the signal lines 13.

With continued reference to FIG. 16, in one or more embodiments, H1=H2, and G1=G2. The distance between a q1-th first shift register circuit group 111 of the H1 first shift register circuit groups 111 and the first central axis L1 is the same as the distance between a q1-th first shift register circuit group 111 of the H2 first shift register circuit groups 111 and the first central axis L1. The distance between a q2-th second shift register circuit group 112 of the G1 second shift register circuit groups 112 and the first central axis L1 is the same as the distance between a q2-th second shift register circuit group 112 of the G2 second shift register circuit group 112 and the first central axis L1. When H1=H2, the H1 first shift register circuit groups 111 in the first display region AA1 and the H1 first shift register circuit groups 111 in the second display region AA2 are disposed symmetrically, thereby further improving the display uniformity of the display panel. Similarly, when G1=G2, the G1 second shift register circuit groups 112 in the first display region AA1 and the G1 second shift register circuit groups 112 in the second display region AA2 are disposed symmetrically, thereby further improving the display uniformity of the display panel.

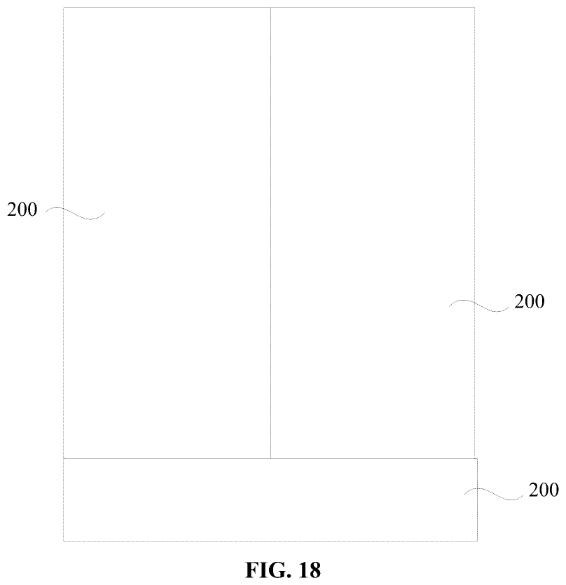

An embodiment of the present disclosure further provides a display device. FIG. 17 is a schematic structural diagram of a display device according to an embodiment of the present disclosure. As shown in FIG. 17, the display device provided in the embodiments of the present disclosure includes the display panel 200 described in any of the embodiments of the present disclosure. The display device may be a mobile phone shown in FIG. 17, or a computer, a television, a smart wearable device, and the like, which is not particularly limited in this embodiment. Further, as shown in FIG. 18, FIG. 18 is a schematic structural diagram of another display device according to an embodiment of the present disclosure. In this embodiment, the display panel 200 adopts a frameless design and may be used for forming a spliced screen as shown in FIG. 18. The spliced screen may be spliced according to required sizes, to satisfy the display requirements of users in scenarios such as advertising display, conference training, and transportation.

The display device provided in the embodiments of the present disclosure includes the technical features of the display panel provided in any of the embodiments of the present disclosure, and has the beneficial effects of the corresponding features.

It is to be noted that the foregoing description merely depicts the preferred embodiments of the present disclosure and the technical principles applied thereto. It is to be understood by those skilled in the art that the present disclosure is not limited to the particular embodiments described herein, and that various variations, rearrangements and substitutions may be made without departing from the scope of protection of the present disclosure. Therefore, although the present disclosure has been described in detail with reference to the above embodiments, the present disclosure is not limited to the above embodiments and may further include other equivalent embodiments without departing from the concept of the present disclosure, and the scope of the present disclosure is defined by the scope of the appended claims.

What is claimed is:

1. A display panel, comprising a substrate and a display region, wherein
the display region comprises a plurality of shift register circuit groups, a shift register circuit group of the plurality of shift register circuit groups comprises a plurality of shift register units disposed sequentially in a first direction, the plurality of shift register circuit groups are arranged in a second direction, the first direction and the second direction intersect, a shift register circuit group of the plurality of shift register circuit groups is configured to output a first scan signal, the plurality of shift register circuit groups at least comprises a first shift register circuit group and a second shift register circuit group, and the first shift register circuit group and the second shift register circuit group are respectively connected to first scan signal lines of different rows; and
the display region further comprises a plurality of signal lines extending in the first direction, the plurality of signal lines comprises a plurality of signal line groups, a signal line group of the plurality of signal line groups is electrically connected to a respective shift register circuit group of the plurality of shift register circuit groups, and different signal line groups among the plurality of signal line groups are electrically connected to different shift register circuit groups among the plurality of shift register circuit groups.

2. The display panel of claim 1, wherein the plurality of signal line groups are disposed in one-to-one correspondence with the plurality of shift register circuit groups.

3. The display panel of claim 2, wherein the display region comprises M shift register circuit groups, wherein M is an integer greater than 1; and
the plurality of signal lines comprises N first signal lines, and the N first signal lines are divided into M signal line groups, wherein N>M, and N is an integer.

4. The display panel of claim 3, wherein the display region further comprises a plurality of pixel circuits, and the plurality of pixel circuits are arranged in the first direction to form a plurality of pixel circuit columns sequentially arranged in the second direction; and
a shift register circuit group of the plurality of shift register circuit groups is disposed in a first spacing region between two adjacent pixel circuit columns among the plurality of pixel circuit columns.

5. The display panel of claim 3, wherein the N first signal lines comprise a first signal line group and a second signal line group; and
the first signal line group comprises R first signal lines, the second signal line group comprises (N−R) first signal lines, the first signal line group is electrically connected to the first shift register circuit group, and the second signal line group is electrically connected to the second shift register circuit group, wherein N>R, and R is an integer.

6. The display panel of claim 5, wherein the display region further comprises a plurality of pixel circuits, and the plurality of pixel circuits are arranged in the second direction to form a plurality of pixel circuit rows sequentially arranged in the first direction;
the plurality of pixel circuit rows are electrically connected to the plurality of shift register units, and a shift register unit of the plurality of shift register units is a first shift register unit or a second shift register unit; and
the shift register unit is disposed in a second spacing region between two adjacent pixel circuit rows among the plurality of pixel circuit rows.

7. The display panel of claim 6, wherein
in the first direction, among the plurality of pixel circuit rows, a shift register unit between an i-th pixel circuit row and an (i+1)-th pixel circuit row is electrically connected to a shift register unit between the (i+1)-th pixel circuit row and an (i+2)-th pixel circuit row through a first cascade wire, wherein i is a positive integer, i≤P−2, and P is a total number of the plurality of pixel circuit rows.

8. The display panel of claim 7, wherein
the first cascade wire and the (i+1)-th pixel circuit row overlap in a direction perpendicular to the substrate; or
the first cascade wire comprises a first branch portion extending in the first direction, a second branch portion extending in the second direction, and a third branch portion extending in the first direction, and the first branch portion, the second branch portion and the third branch portion are electrically connected in sequence; and the first cascade wire and the plurality of pixel circuits do not overlap in a direction perpendicular to the substrate.

9. The display panel of claim 6, wherein the first shift register circuit group further comprises a first auxiliary shift register unit, and the second shift register circuit group further comprises a second auxiliary shift register unit;
in the first direction, two adjacent first shift register units are connected in cascade through at least one first auxiliary shift register unit; and
in the first direction, two adjacent second shift register units are connected in cascade through at least one second auxiliary shift register unit.

10. The display panel of claim 9, wherein
among the plurality of pixel circuit rows, the first shift register unit and the second auxiliary shift register unit are located between a t-th pixel circuit row and a (t+1)-th pixel circuit row, and the second shift register unit and the first auxiliary shift register unit are located between the (t+1)-th pixel circuit row and a (t+2)-th pixel circuit row, wherein 1≤t≤P−2, and P is a total number of the plurality of pixel circuit rows.

11. The display panel of claim 9, wherein in the first direction, among the plurality of pixel circuit rows, a shift register unit connected to an i-th pixel circuit row is the first shift register unit, and a shift register unit connected to an (i+1)-th pixel circuit row is connected is the second shift register unit, wherein i is an integer greater than zero; and
in the first direction, two adjacent first shift register units are connected in cascade through the first auxiliary shift register unit; and in the first direction, two adjacent second shift register units are connected in cascade through the second auxiliary shift register unit.

12. The display panel of claim 9, wherein the first shift register unit, the first auxiliary shift register unit, the second shift register unit and the second auxiliary shift register unit each comprise a cascade output terminal;
at least one of the following is satisfied:
in the second direction, among the plurality of pixel circuit rows, cascade output terminals of the first shift register unit and the second auxiliary shift register unit located between a t-th pixel circuit row and a (t+1)-th pixel circuit row are electrically connected through a first horizontal wire; or
in the second direction, among the plurality of pixel circuit rows, cascade output terminals of the first auxiliary shift register unit and the second shift register unit located between a (t+1)-th pixel circuit row and a (t+2)-th pixel circuit row are electrically connected through a second horizontal wire.

13. The display panel of claim 12, wherein
in the second direction, signal lines electrically connected to the first shift register circuit group are located on a side of the first shift register circuit group facing away from the second shift register circuit group; and
in the second direction, signal lines electrically connected to the second shift register circuit group are located on a side of the second shift register circuit group facing away from the first shift register circuit group.

14. The display panel of claim 12, wherein at least one of the following is satisfied:
in the second direction, at least part of signal lines electrically connected to the first shift register circuit group are disposed between the first shift register circuit group and the second shift register circuit group; or
in the second direction, at least part of signal lines electrically connected to the second shift register circuit group are disposed between the first shift register circuit group and the second shift register circuit group.

15. The display panel of claim 14, wherein a signal line disposed between the first shift register circuit group and the second shift register circuit group is a second signal line;
the first horizontal wire and the second signal line are located in different film layers, and the second horizontal wire and the second signal line are located in different film layers; or
the second signal line, the first horizontal wire and the second horizontal wire are located on a first film layer, and the first horizontal wire and the second horizontal wire are each provided with a cross-bridge disposed on a second film layer.

16. The display panel of claim 14, wherein the plurality of signal lines further comprise third signal lines, and a third signal line of the third signal lines comprises a first clock signal line, a second clock signal line, a first level signal line, a second level signal line, and a start signal line;
the third signal lines are electrically connected to the plurality of shift register circuit groups in one-to-one correspondence, or the first shift register circuit group and the second shift register circuit group share the third signal lines; and
a signal line disposed between the first shift register circuit group and the second shift register circuit group is the first level signal line and the second level signal line.

17. The display panel of claim 9, wherein
each of the first auxiliary shift register unit and the second auxiliary shift register unit comprises a first control module, a second control module and a lower-level trigger module; wherein the first control module is electrically connected to a signal input terminal, a first clock terminal, a second clock terminal, a first level terminal and a second level terminal, separately, and the first control module is electrically connected to the lower-level trigger module at a first node, to control a potential of the first node; the second control module is electrically connected to a reset terminal, the signal input terminal, the first clock terminal, the second clock terminal, the first level terminal and the second level terminal, separately, and the second control module is electrically connected to the lower-level trigger module at a second node, to control a potential of the second node; and the lower-level trigger module is configured to control a cascade signal terminal to output a trigger signal according to the potential of the first node and the potential of the second node; or
each of the first shift register unit and the second shift register unit comprises a first control module, a second control module, a lower-level trigger module and an output module; wherein the first control module is electrically connected to a signal input terminal, a first clock terminal, a second clock terminal, a first level terminal and a second level terminal, separately, and the first control module is electrically connected to the lower-level trigger module at a first node, to control a potential of the first node; the second control module is electrically connected to a reset terminal, the signal input terminal, the first clock terminal, the second clock terminal, the first level terminal and the second level terminal, separately, and the second control module is electrically connected to the lower-level trigger module at a second node, to control a potential of the second node; the lower-level trigger module is configured to control a cascade signal terminal to output a trigger signal according to the potential of the first node and the potential of the second node; and the output module is electrically connected to a third level terminal and a sweep clock signal, separately, and the output module is configured to output a sweep signal according to the trigger signal.

18. The display panel of claim 16, further comprising first signal terminals, wherein the first signal terminals are electrically connected to the third signal lines in one-to-one correspondence; and
the first shift register circuit group and the second shift register circuit group share a first signal terminal of the first signal terminals;
wherein in the first direction, the first signal terminals are disposed on a side of the first shift register circuit group or a side of the second shift register circuit group;
same signal lines between a third signal line of the first shift register circuit group and a third signal line of the second shift register circuit group are electrically connected to each other through a connection line; and
in the first direction, the connection line is disposed on a side of the first shift register circuit group or the second shift register circuit group facing away from the first signal terminals.

19. The display panel of claim 5, wherein the display region comprises a first display region and a second display region, a first central axis of the display region is located between the first display region and the second display region, and the first central axis extends in the first direction; and
the first display region comprises H1 first shift register circuit groups and G1 second shift register circuit groups, and the second display region comprises H2 first shift register circuit groups and G2 second shift register circuit groups, wherein H1, G1, H2 and G2 are each a positive integer;
wherein H1=H2, and G1=G2; and a distance between a q1-th first shift register circuit group of the H1 first shift register circuit groups and the first central axis is the same as a distance between a ql-th first shift register circuit group of the H2 first shift register circuit groups and the first central axis, and a distance between a q2-th second shift register circuit group of the G1 second shift register circuit groups and the first central axis is the same as a distance between a q2-th second shift register circuit group of the G2 second shift register circuit groups and the first central axis.

20. A display device comprising a display panel, wherein the display panel comprises a substrate and a display region, wherein
the display region comprises a plurality of shift register circuit groups, a shift register circuit group of the plurality of shift register circuit groups comprises a plurality of shift register units disposed sequentially in a first direction, the plurality of shift register circuit groups are arranged in a second direction, the first direction and the second direction intersect, a shift register circuit group of the plurality of shift register circuit groups is configured to output a first scan signal, the plurality of shift register circuit groups at least comprises a first shift register circuit group and a second shift register circuit group, and the first shift register circuit group and the second shift register circuit group are respectively connected to first scan signal lines of different rows; and
the display region further comprises a plurality of signal lines extending in the first direction, the plurality of signal lines comprises a plurality of signal line groups, a signal line group of the plurality of signal line groups is electrically connected to a respective shift register circuit group of the plurality of shift register circuit groups, and different signal line groups among the plurality of signal line groups are electrically connected to different shift register circuit groups among the plurality of shift register circuit groups.
